(19) United States
(12) Patent Application Publication
(10) Pub. No.: US 2002/0037624 A1
(43) Pub. Date: Mar. 28, 2002

(54) Capacitor and method for fabricating semiconductor device

(76) Inventors: Yoshihiro Mori, Osaka (JP); Yasutoshi Okuno, Kyoto (JP); Akihiko Tsuzumitani, Osaka (JP)

Correspondence Address: NIXON PEABODY, LLP, 8180 GREENSBORO DRIVE, SUITE 800, MCLEAN, VA, 22102, US

(21) Appl. No.: 09/942,038

(22) Filed: Aug. 30, 2001

(30) Foreign Application Priority Data
Sep. 1, 2000 (JP) 2000-265284

(51) Int. Cl. H01L 21/20

(52) U.S. Cl. 438/396

(57) ABSTRACT

After a lower electrode made of Pt, for example, has been formed, impurity atoms (e.g., hydrogen atoms) which suppress decrease in stiffness of the electrode at a high temperature are introduced into the lower electrode. Then, even when the lower electrode is heated to a high temperature in an oxidizing atmosphere in the subsequent process step of forming a capacitive insulating film of e.g., BST on the lower electrode, the decrease in stiffness of the lower electrode is suppressible. Accordingly, it is possible to prevent the deformation of the lower electrode, which might otherwise result from the coagulation of metal atoms such as Pt atoms in the lower electrode.

### BACKGROUND OF THE INVENTION

The present invention relates to a capacitor in which a dielectric film is interposed between two electrodes and a method for fabricating a semiconductor device including the electrodes and more particularly relates to measures to prevent the deformation of the electrodes.

In a capacitor including a capacitive insulating film made of a high-dielectric-constant or ferroelectric material, the electrodes thereof have been made of a noble or refractory metal. This is because the film of a high-dielectric-constant or ferroelectric material is normally deposited through chemical reactions and shows strong oxidizability. Thus, materials for the electrodes need to be as chemically stable as possible.

If the capacitive insulating film is made of a high-dielectric-constant material such as tantalum pentoxide (Ta₂O₅), the electrodes may be made of ruthenium (Ru), tungsten (W) or molybdenum (Mo), for example.

Or, if the capacitive insulating film is made of barium strontium titanium oxide (Ba₁₋ₓSrₓTiO₃) (BST), the electrodes may be made of Ru, ruthenium dioxide (RuO₂), platinum (Pt) or iridium (Ir), for example.

Or, if the capacitive insulating film is made of a ferroelectric material such as strontium bismuth tantalum oxide (SBT) or lead zirconium titanium oxide (PZT), the electrodes may be made of Pt, Ir or iridium dioxide (IrO₂), for example.

Hereinafter, the structure of a known capacitor disclosed in Japanese Laid-Open Publication No. 11-74488 will be described with reference to FIG. 1. The capacitor includes a capacitive insulating film made of BST. The capacitor is used as a storage capacitor for a DRAM memory cell. The memory cell includes a memory cell transistor (not shown) with an MISFET structure that includes gate insulating film, gate electrode and source/drain regions on a semiconductor substrate 100. As shown in FIG. 1, the memory cell also includes interlevel dielectric film 106, polysilicon plug 108, silicide layer 107 (e.g., cobalt silicide layer), barrier layer 105 and contact layer 104 over the substrate 100. The interlevel dielectric film 106 is made of silicon dioxide (SiO₂) or silicon nitride (SiN). The polysilicon plug 108 has been formed to fill in a contact hole. The contact hole is formed to pass through the interlevel dielectric film 106 and reach the source region of the semiconductor substrate 100. The silicide layer 107 is formed on the polysilicon plug 108. The barrier layer 105 is made of titanium aluminum nitride (TiAlN). The contact layer 104 is made of TiAlN and formed to cover the interlevel dielectric film 106 as well as the barrier layer 105. Further, a capacitor is formed over the contact layer 104. The capacitor includes lower electrode 101, capacitive insulating film 102 and upper electrode 103. The lower electrode 101 is made of Pt and covers the contact layer 104. The capacitive insulating film 102 is a BST film with a thickness of about 30 nm and covers the lower electrode 101. The upper electrode 103 is made of Pt. The stack of the lower electrode 101, capacitive insulating film 102 and upper electrode 103 is used as a storage capacitor. In this first prior art example, the lower electrode 101 has a thickness of about 500 nm and has a sufficient mechanical strength. However, if the lower electrode 101 was formed directly on an underlying layer (e.g., the interlevel dielectric film 106 or silicide layer 107), the electrode 101 would poorly adhere to the underlying layer and might possibly peel off. Thus, in this example, the contact layer 104 of TiAlN and the barrier layer 105 are formed under the lower electrode 101. The barrier layer 105 also prevents the polysilicon plug 108 from oxidizing.

Since a Pt film is very stable chemically, it is very difficult in this case to pattern the Pt film with the thickness of 500 nm to form the lower electrode 101 shown in FIG. 1. In the example shown in FIG. 1, the side faces of the lower electrode 101 are also used as an electrode. However, if the area of the lower electrode 101 is increased or if the capacitive insulating film is made of a material with a higher dielectric constant, a sufficient capacitance can be obtained even by the use of a lower electrode with narrow side faces. Accordingly, the lower electrode may have its thickness reduced. FIG. 3 illustrates an exemplary capacitor structure, including a lower electrode 101 of a thinner Pt film, for a DRAM memory cell. In FIG. 3, each member identified by the reference numeral used in FIG. 1 is the same as the counter-part shown in FIG. 1.

A design rule of 0.15 μm or less is now a commonplace for a DRAM memory cell as a result of the recent downsizing trend. In a situation like this, the capacitor of a DRAM memory cell needs to have the thickness of its lower electrode further reduced. FIG. 2 is a cross-sectional view illustrating the structure of a cupped capacitor contributing to reduction in thickness of the lower electrode. The memory cell shown in FIG. 2 also includes the semiconductor substrate 100, polysilicon plug 108, silicide layer 107 and barrier layer 105 of TiAlN as in the structure shown in FIG. 1. The memory cell further includes contact layer 114, lower electrode 111, capacitive insulating film 112 and upper electrode 113. The contact layer 114 is made of TiAlN and covers the side faces and bottom of a recess formed in the interlevel dielectric film 106. The lower electrode 111 is formed out of a Pt thin film on the contact layer 114. The capacitive insulating film 112 is made of a BST film with a thickness of about 25 nm. The upper electrode 113 is made of Pt. To form a memory cell of a small size, the lower electrode 111 needs to have its thickness reduced to about 10 to 20 nm. Thus, the lower electrode 111 does not have a sufficient mechanical strength and has to be supported firmly by the interlevel dielectric film 106 existing under the electrode 111. Therefore, the contact layer 114 is formed out of an extremely thin titanium film to get the lower electrode 111 strongly adhered to the interlevel dielectric film 106.

However, the present inventors found by research that the Pt thin lower electrode shown in FIG. 2 or 3 has the following drawbacks that were not observed in the thick Pt lower electrode shown in FIG. 1.

FIGS. 4 and 5 are cross-sectional views illustrating how the capacitors shown in FIGS. 2 and 3 may change their structure when annealed in an oxygen atmosphere. As shown in FIGS. 4 and 5, the Pt atoms existing in the lower electrode 111 or 101 coagulate to form voids Rvo in the lower electrode 111 or 101 when the capacitor is annealed in the oxygen atmosphere.

In a fabrication process of a capacitor, examples of the heating process steps carried out in an oxygen atmosphere include the process step of depositing a BST film as the capacitive insulating film 112 or 102 by a chemical vapor deposition (CVD) process and a subsequent annealing process for supplying oxygen to the BST film. These process steps cannot be omitted. Thus, to eliminate the voids Rvo shown in FIGS. 4 and 5, the structure of the Pt thin film itself has to be so modified as to withstand the annealing processes performed in an oxygen atmosphere.

Therefore, to modify the structure of the Pt thin film, the present inventors carried out the following research.

A main reason for the formation of the voids Rvo would be that the Pt thin film easily rounds like a ball at a high temperature because the strength of the Pt thin film decreases at the high temperature and the Pt thin film has a high surface tension. We also found that stress changed very steeply at a temperature of about 400° C. in an atmosphere containing 5 to 20% of oxygen at the atmospheric pressure. FIG. 6 is a graph illustrating a variation in stress applied to a Pt thin film, as measured using a laser reflection, where the Pt thin film deposited to a thickness of about 100 nm on a silicon wafer was heated to a high temperature in an atmosphere containing oxygen. In FIG. 6, the abscissa indicates the temperature (° C.) while the ordinate indicates the stress (MPa). In this case, tensile stresses are represented as positive ordinates. As shown in FIG. 6, we believe that a compressive stress would have been applied to the as. dep. (as deposited) Pt thin film on the silicon wafer. However, considering the analysis principle of the laser measurement, the zero stress point is not so accurate in FIG. 6. Rather, we must take the stress variation represented by this data into account. Further, if the silicon wafer is heated, the stress would gradually change into a compressive one since the Pt thin film has a thermal expansion coefficient greater than that of the silicon wafer. However, we will continue our discussion with the stress variation resulting from the difference in thermal expansion coefficient regarded as negligible. As shown in FIG. 6, once the temperature exceeds about 300° C., the stress applied to the Pt thin film starts changing steeply. And we found a correlation between such a steep stress variation and the formation of the voids. The voids Rvo would be formed as follows. With the steep changes in stress, the movement, growth (aggregation) or dislocation of grains would be activated. As a result, some of the Pt atoms would coagulate under the surface tension and part of the Pt thin film would peel off the contact layer and round itself.

### SUMMARY OF THE INVENTION

It is therefore an object of the present invention to prevent the creation of voids, which might result from the deformation of an electrode of Pt, for example, for a capacitor, by taking measures to suppress the decrease in stiffness of the electrode material at least at a high temperature.

A first inventive capacitor includes: a first electrode made of a metal; a second electrode made of a conductor; and a capacitive insulating film existing between the first and second electrodes. The first electrode has been doped with impurity atoms that suppress decrease in stiffness of the first electrode at a high temperature.

According to the present invention, even if the first electrode is heated to a high temperature, the stiffness thereof is kept high. Thus, the deformation of the electrode can be prevented. This is to say, it is possible to avoid an unfavorable phenomenon such as void creation that might otherwise result from the coagulation of metal atoms.

In one embodiment of the present invention, the first electrode may be made of a platinum noble metal. In such an embodiment, the first electrode can be stabilized chemically and thus the reliability and charge storage characteristic of the capacitor can be kept high.

In another embodiment of the present invention, the impurity atoms may be hydrogen atoms. Then, the hydrogen atoms bond to metal atoms existing in the first electrode, thereby suppressing the movement of the metal atoms. Accordingly, the deformation of the first electrode can be reduced more effectively.

In still another embodiment, the capacitive insulating film may be a dielectric film made of an oxide. Then, the first electrode will not be deformed even if the electrode is exposed to an oxidizing atmosphere while the dielectric film is being deposited.

In yet another embodiment, the first electrode may have a thickness of 100 nm or less at the thinnest part thereof. Then, the present invention is applicable particularly effectively.

In yet another embodiment, the second electrode has preferably been doped with impurity atoms that suppress decrease in stiffness of the second electrode at a high temperature. Then, the second electrode can have its thickness reduced with high reliability ensured.

A second inventive capacitor includes: a first electrode made of a noble metal or a refractory metal; a second electrode made of a conductor; and a capacitive insulating film existing between the first and second electrodes. The first electrode contains hydrogen.

According to the present invention, hydrogen atoms bond to metal atoms existing in the noble or refractory metal electrode, and the movement of the metal atoms is suppressed. Accordingly, the first electrode is not deformed.

A first inventive method is for use to fabricate a semiconductor device that includes, as a component thereof, an electrode made of a noble metal or a refractory metal. The method includes the steps of: a) forming the electrode and b) annealing the electrode in a reducing atmosphere.

According to the first inventive method, the electrode is annealed in a reducing atmosphere. Thus, the partial oxidation of the electrode can be suppressed even when the electrode is annealed in an oxidizing atmosphere in a subsequent step. Accordingly, the electrode is not deformed.

In one embodiment of the present invention, the method may further include the step of forming, on the electrode, a dielectric film for a capacitor after the step b) has been performed. In such an embodiment, this method is applicable to forming a capacitor.

In another embodiment of the present invention, the step b) is preferably performed in an atmosphere that contains hydrogen and that has been created as the reducing atmosphere.

A second inventive method is for use to fabricate a semiconductor device that includes an electrode as a component. The method includes the steps of: a) forming the electrode; b) annealing the electrode in a reducing atmosphere; and c) forming an insulating film made of an oxide on the electrode.

According to the second inventive method, the partial oxidation of the electrode can be suppressed even if the electrode is heated to a high temperature in an oxidizing atmosphere in the step c). Accordingly, the electrode is not deformed.

In one embodiment of the present invention, the method may further include the step of forming, on the insulating film, another electrode for a capacitor after the step c) has been performed. In such an embodiment, the present invention is applicable to fabricating a semiconductor device including a capacitor.

### BRIEF DESCRIPTION OF THE DRAWINGS

FIG. 1 is a cross-sectional view illustrating the structure of a known capacitor including a capacitive insulating film made of BST.

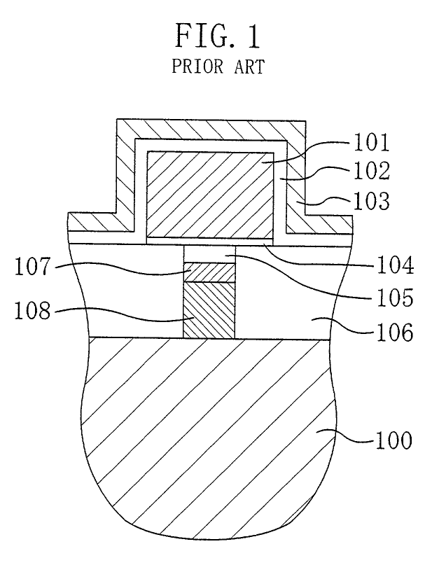

FIG. 2 is a cross-sectional view illustrating the structure of a cupped capacitor contributing to reduction in thickness of a lower electrode.

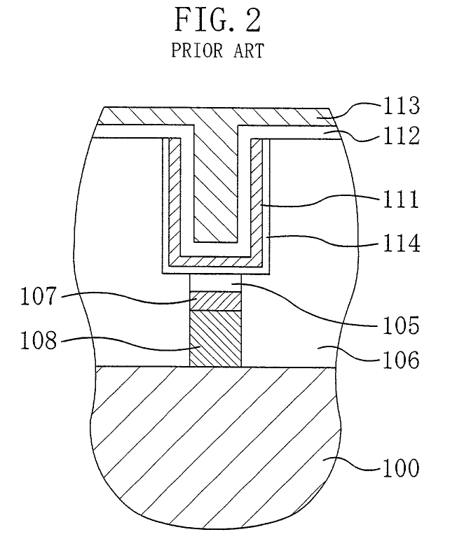

FIG. 3 illustrates an exemplary capacitor structure, including a lower electrode of a thinner Pt film, for a DRAM memory cell.

FIG. 4 is a cross-sectional view illustrating how the capacitor shown in FIG. 2 may change its structure when annealed in an oxygen atmosphere.

FIG. 5 is a cross-sectional view illustrating how the capacitor shown in FIG. 3 may change its structure when annealed in an oxygen atmosphere.

FIG. 6 is a graph illustrating a variation in stress applied to a Pt thin film that was deposited on a silicon wafer and heated to a high temperature immediately.

FIG. 7 is a graph illustrating a variation in stress applied to a Pt thin film that was deposited on a silicon wafer, subjected to a hydrogen treatment and then heated to a high temperature.

FIG. 8 is a graph illustrating the Young's moduli of Pt thin films, deposited on a wafer under mutually different process conditions, as measured by a micro-Vickers hardness test.

FIGS. 9A though 9C are cross-sectional views illustrating exemplary process steps for fabricating a semiconductor device (i.e., a capacitor in this case) in accordance with the present invention.

### DESCRIPTION OF THE PREFERRED EMBODIMENTS

Experimental Data as the Basis of This Invention

The present inventors found, based on the following experimental data, that the addition of a light element such as hydrogen suppressed the decrease in strength of the Pt thin film.

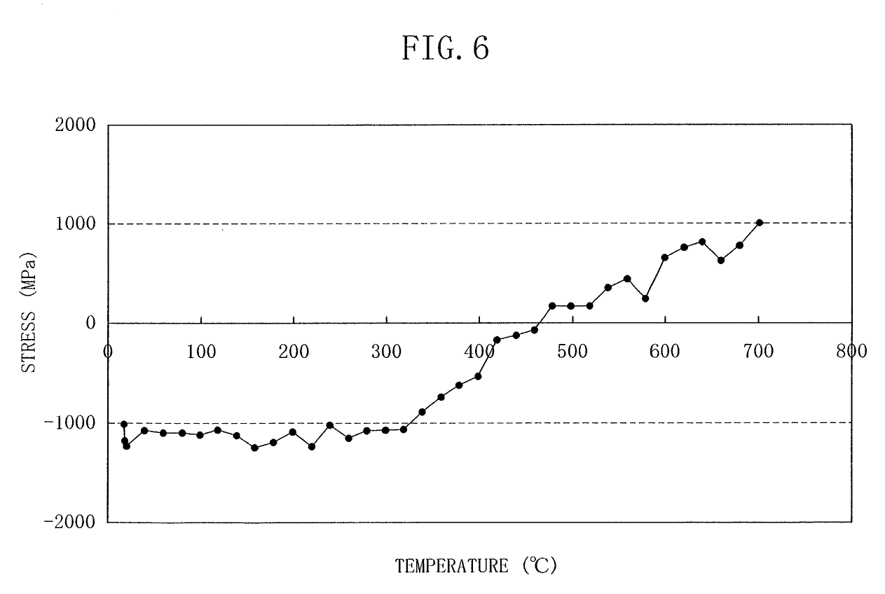

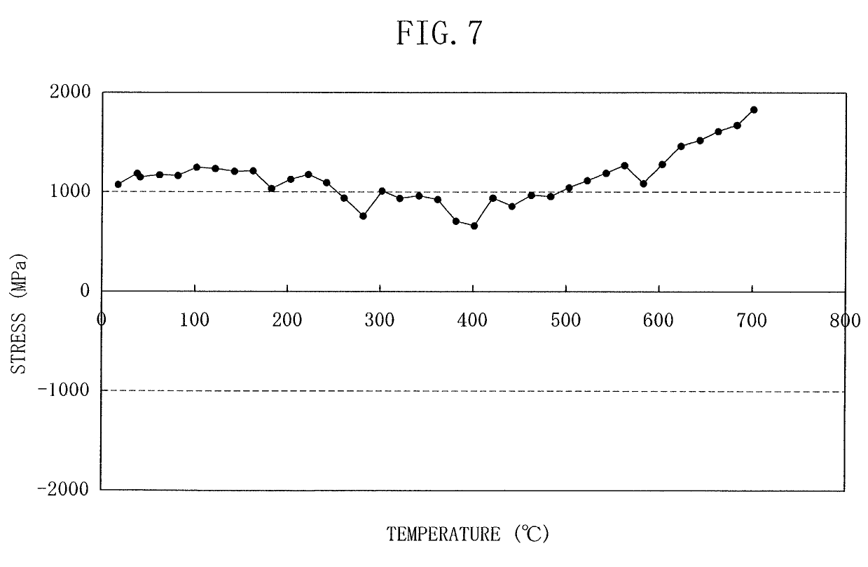

FIG. 7 is a graph illustrating a variation in stress applied to a Pt thin film, which was deposited to a thickness of about 100 nm on a silicon wafer, as measured using a laser reflection. In this case, the Pt thin film was annealed for 5 to 10 minutes at a temperature of about 450-500° C. at the atmospheric pressure in an inert gas atmosphere containing hydrogen at several percent. Then, the Pt thin film was further annealed under the conditions shown in FIG. 6, i.e., in the atmosphere containing oxygen. In FIG. 7, the abscissa indicates the temperature (° C.) while the ordinate indicates the stress (MPa). In this case, tensile stresses are represented as positive ordinates. In this example, we believe that if the Pt thin film on the silicon wafer is annealed with hydrogen, the types of stress applied to the Pt thin film would change; a compressive stress applied to the Pt thin film in the as. dep state would change into a tensile one as a result of such an annealing process. However, considering the analysis principle of the laser measurement, the zero stress point is not so accurate in FIG. 7. Rather, we must take the stress variation represented by this data into account. Further, if the silicon wafer is heated, the tensile stress would gradually decrease (i.e., change into a compressive one) since the Pt thin film has a thermal expansion coefficient greater than that of the silicon wafer. However, we will continue our discussion with the stress variation resulting from the difference in thermal expansion coefficient regarded as negligible. As shown in FIG. 7, where the hydrogen annealing was performed, no steep stress variation was observed unlike the example shown in FIG. 6 even when the temperature was further raised.

We could not clarify fully the reason why no steep stress variation was observed. However, since the stress did not change steeply, we believe that no great force would be applied to the Pt thin film even when the Pt thin film was annealed in the atmosphere containing oxygen. Thus none of the Pt atoms existing in the Pt thin film would coagulate and no part of the Pt thin film would peel off.

On the other hand, the Pt thin film would have had its strength increased to some extent by the addition of the hydrogen. Specifically, many of the hydrogen atoms introduced into the Pt thin film would be released from the Pt thin film as the temperature rose. However, not all of the hydrogen atoms would be released and some atoms should remain in the Pt thin film. We believe that those hydrogen atoms remaining in the Pt thin film should have a strong tendency to segregate near grain boundaries and around defects such as dislocations as impurities do normally. Thus, there's good reason to believe that the hydrogen atoms segregated near the grain boundaries should prevent the movement or growth (aggregation) of the grains and that the hydrogen atoms that had reached the vicinity of the dislocations should pin those dislocations and suppress the movement thereof. Hydrogen atoms, in particular, bond to metal atoms such as Pt atoms in a crystal lattice. Thus, we believe that hydrogen atoms should greatly interfere with the movement of the dislocations and the grains. And we believe that the Pt thin film should maintain its strength even at a high temperature because the dislocations get stuck and the mobility of the grains decreases in the Pt thin film.

Further, since the hydrogen atoms added bond to Pt atoms, the surface tension of the Pt thin film should decrease and thus the stress causing the coagulation of the Pt atoms should also decrease. We believe that this could also be one of the reasons why no steep stress change was observed. The addition of the hydrogen at least reduces the work function of Pt. Thus, such change in surface state might possibly have made the difference in characteristics between the Pt thin film annealed with hydrogen and the Pt thin film that was not subjected to the hydrogen treatment.

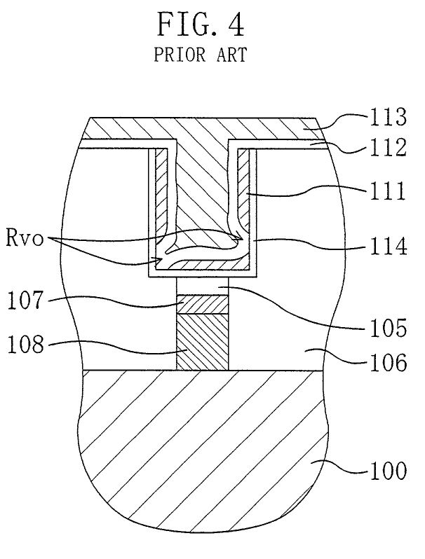

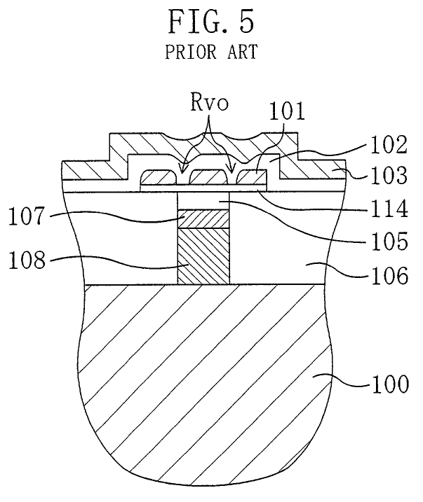

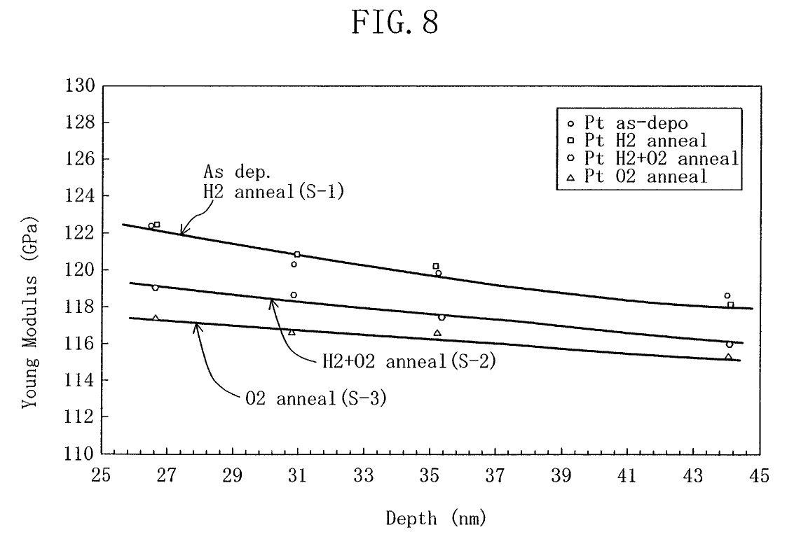

FIG. 8 is a graph illustrating the Young's moduli of Pt thin films, deposited to a thickness of about 100 nm on a wafer under mutually different process conditions, as measured by a micro-Vickers hardness test. In FIG. 8, the abscissa indicates the depth (nm) of a micro-Vickers diamond pyramid pushed while the ordinate indicates the Young's modulus (GPa). In this case, where the micro-Vickers diamond pyramid is pushed deep, the measured values will be affected by the Young's modulus of the underlying layer. On the other hand, where the micro-Vickers diamond pyramid is pushed shallow, the measured values will be greatly variable. Therefore, the micro-Vickers diamond pyramid is pushed to different depths so that the measurement can be reliable enough. As shown in FIG. 8, the samples S-1 (Pt as dep. (as deposited) thin film and Pt thin film annealed in a hydrogen atmosphere) showed the highest Young's modulus. The sample S-2 (Pt thin film annealed in a hydrogen and oxygen atmosphere) showed the second highest Young's modulus. The sample S-3 (Pt thin film annealed in an oxidizing atmosphere) showed the lowest Young's modulus. The sample S-3 showed the lowest Young's modulus because the grains of the sample S-3 should have grown excessively as a result of the annealing process performed in the oxidizing atmosphere. In an actual fabrication process of a capacitor, the temperature is kept high in an oxidizing atmosphere while a BST film is deposited on a Pt thin film. Thus, during the deposition process of the BST film, the Pt thin film should be subjected to a process similar to that performed on the sample S-3. We confirmed that in the samples S-1, the hydrogen-annealed Pt thin film showed a Young's modulus (stiffness) no lower than that of the Pt as. dep. (as deposited) thin film. That is to say, the Young's modulus improved as compared to the Pt thin film fabricated by the known process. The Young's modulus could be kept at such a high level and the stress did not change so steeply as described above. Accordingly, the Pt atoms existing in the Pt thin film should not coagulate and form any void Rvo (see FIGS. 4 and 5) during the deposition process of the BST film.

Other Materials Applicable in the Present Invention

The stiffness of a thin film can be increased not only in the Pt thin film but also in a thin film of a non-Pt metal such as a platinum noble metal like iridium (Ir), ruthenium (Ru), rhodium (Rh), palladium (Pd) or an alloy of these metals. Similar effects are also attainable for so-called “refractory metals” such as tungsten (W), tantalum (Ta), titanium (Ti), vanadium (v), niobium (Nb), chromium (Cr), zirconium (Zr), hafnium (Hf) or alloys thereof. However, we found as a result of our experiments that where a film of any of these metals had a thickness of more than 100 nm, no metal atoms existing in the metal film coagulated and no voids were formed unlike the situations shown in FIGS. 4 and 5 even if the film was not subjected to the hydrogen treatment. Thus, it is not so meaningful to apply this invention to such a metal film with a thickness of more than 100 nm.

Also, the impurity to be added is not limited to hydrogen but may be a light element such as beryllium (Be) or boron (B). Such a light element may be vaporized when heated or evaporated without evaporating a chemical compound with a higher vapor pressure. Accordingly, the light element may be supplied in gas phase after the lower electrode has been formed. Alternatively, ions of such a light element may also be implanted into the Pt thin film. In that case, the impurity atoms existing in the Pt film may be in a thermally non-equilibrium state because the implant dose and doped region are easily controllable.

Moreover, this invention is particularly effectively applied to depositing, on an electrode of e.g., Pt, a high-dielectric-constant or ferroelectric film of a perovskite material like BST, SBT or PZT or a high-dielectric-constant film of Ta₂O₅, ZrO₂ and TiO₂, for example. This is because these films are deposited in a strongly oxidizing atmosphere in many cases.

Embodiment of Fabricating Method

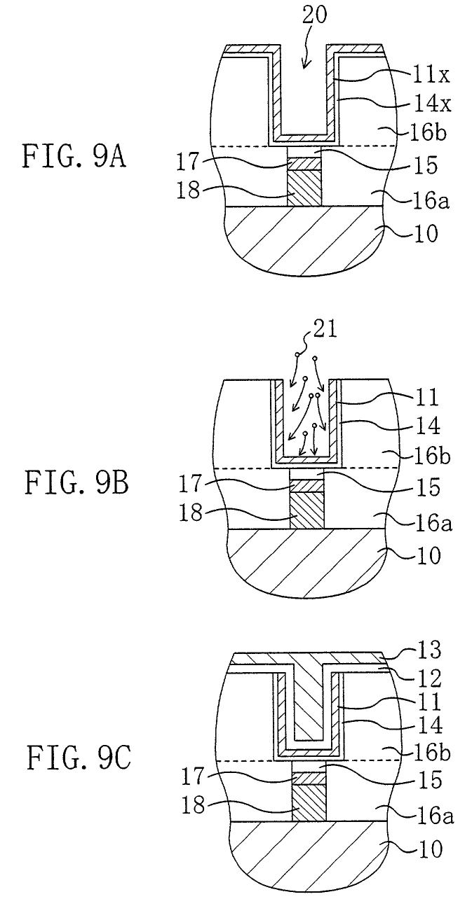

FIGS. 9A though 9C are cross-sectional views illustrating exemplary process steps for fabricating a semiconductor device (i.e., a capacitor in this case) in accordance with the present invention.

In a DRAM memory cell, for example, a memory cell transistor, including gate electrode and source/drain regions, has been formed on a semiconductor substrate (wafer) 10 with a diameter of e.g., 8 inches before the process step shown in FIG. 9A is started. First, a lower interlevel dielectric film 16a of SiO₂ or SiN is formed on the semiconductor substrate 10 by a CVD process. Then, a contact hole is formed by photolithographic and dry etching processes through the interlevel dielectric film 16a to reach part (the source region of the memory cell transistor when this invention is applied to a DRAM) of the semiconductor substrate 10. Next, a polysilicon plug 18 is formed out of a polysilicon film to fill in the contact hole, and then the surface of the polysilicon plug 18 is silicided, thereby forming a silicide layer 17. Then, a barrier layer 15 of TiAlN is formed on the silicide layer 17 in the contact hole. At this point in time, the polysilicon plug 18 is electrically connected to the active region (source region) of the memory cell transistor directly or by way of another conductor.

Next, an upper interlevel dielectric film 16b of SiO₂ or SiN is formed on the substrate by a CVD process. Then, a recess 20 is formed by photolithographic and dry etching processes through the upper interlevel dielectric film 16b to reach the uppermost part of the polysilicon plug 18. The recess 20 may have a diameter of 0.4 μm while the contact hole formed in the lower interlevel dielectric film 16a may have a diameter of 0.15 μm. Then, an extremely thin film of Ti 14x to be a contact layer is formed on the inner faces of the recess 20 and over the upper interlevel dielectric film 16b by a sputtering process. Thereafter, a Pt thin film 11x is deposited to a thickness of about 20 nm (at the thinnest part) on the Ti film 14x by a sputtering process.

Next, in the process step shown in FIG. 9B, excessive parts of the Pt thin film 11x and the Ti film 14x, located outside of the recess 20, are removed, thereby forming a lower electrode 11 and a contact layer 14. Then, an annealing process is performed at 500° C. for 5 minutes in an argon gas atmosphere containing 4% hydrogen. In this process step, hydrogen atoms 21 are introduced into the lower electrode 11 of the Pt thin film.

Next, in the process step shown in FIG. 9C, a capacitive insulating film 12 of BST is deposited to a thickness of about 25-30 nm at about 500° C. in an oxidizing atmosphere by an MOCVD process, for example. In this case, a very small quantity of hydrogen existing in the lower electrode 11 prevents the Pt atoms from coagulating in the lower electrode 11. Thus, the voids Rvo shown in FIG. 4 or 5 are not formed. Next, an annealing process is performed at about 600° C. in an atmosphere containing oxygen to get the BST film crystallized. However, the Pt atoms making up the lower electrode 11 do not coagulate, either, in this process step. Then, an upper electrode 13 of platinum is formed on the capacitive insulating film 12 by a sputtering process.

In this embodiment, in the process step shown in FIG. 9B, the lower electrode 11 and the contact layer 14 are formed by removing the excessive parts of the Pt thin film 11x and Ti film 14x located outside of the recess 20 and then the annealing process is performed in the argon atmosphere containing hydrogen. Naturally, the present invention is also effective even if these process steps are performed in reverse order.

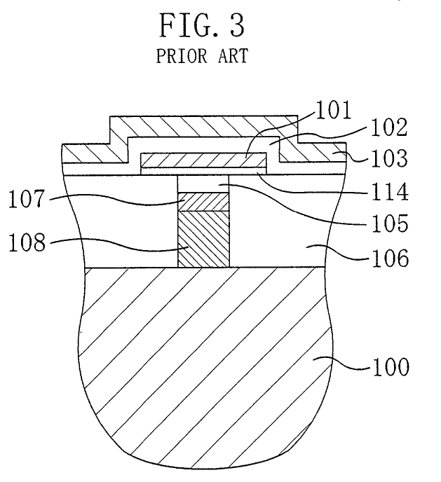

For the foregoing embodiment, we described an example in which the lower electrode is formed on the walls of the recess 20. A capacitor including a platelike lower electrode as shown in FIG. 3 may also be subjected to substantially the same annealing process as that described for the embodiment.

Furthermore, only the lower electrode is supposed to be annealed with hydrogen in the foregoing embodiment. However, where the upper electrode should have its thickness reduced to 100 nm or less, the upper electrode formed may also be subjected to a hydrogen annealing treatment. Then, it is possible to suppress its deformation that might otherwise be caused in a subsequent process step by the coagulation of metal atoms existing in the upper electrode.

What is claimed is:

1. A capacitor comprising:
a first electrode made of a metal;
a second electrode made of a conductor; and
a capacitive insulating film existing between the first and second electrodes,
wherein the first electrode has been doped with impurity atoms that suppress decrease in stiffness of the first electrode at a high temperature.

2. The capacitor of claim 1, wherein the first electrode is made of a platinum noble metal.

3. The capacitor of claim 1, wherein the impurity atoms are hydrogen atoms.

4. The capacitor of claim 1, wherein the first electrode has a thickness of 100 nm or less at the thinnest part thereof.

5. The capacitor of claim 1, wherein the capacitive insulating film is a dielectric film made of an oxide.

6. The capacitor of claim 1, wherein the second electrode has been doped with impurity atoms that suppress decrease in stiffness of the second electrode at a high temperature.

7. A capacitor comprising:
a first electrode made of a noble metal or a refractory metal;
a second electrode made of a conductor; and
a capacitive insulating film existing between the first and second electrodes,
wherein the first electrode contains hydrogen.

8. The capacitor of claim 7, wherein the first electrode has a thickness of 100 nm or less at the thinnest part thereof.

9. The capacitor of claim 8, wherein the capacitive insulating film is a dielectric film made of an oxide.

10. A method for fabricating a semiconductor device that includes, as a component thereof, an electrode made of a noble metal or a refractory metal, the method comprising the steps of:
a) forming the electrode; and
b) annealing the electrode in a reducing atmosphere.

11. The method of claim 10, further comprising the step of forming, on the electrode, a dielectric film for a capacitor after the step b) has been performed.

12. The method of claim 10, wherein the step b) is performed in an atmosphere that contains hydrogen and that has been created as the reducing atmosphere.

13. A method for fabricating a semiconductor device that includes an electrode as a component, the method comprising the steps of:
a) forming the electrode;
b) annealing the electrode in a reducing atmosphere; and
c) forming an insulating film made of an oxide on the electrode.

14. The method of claim 13, wherein the step b) is performed in an atmosphere that contains hydrogen and that has been created as the reducing atmosphere, and
wherein the method further comprises the step of forming, on the insulating film, another electrode for a capacitor after the step c) has been performed.

15. The method of claim 13, wherein the step b) is performed in an atmosphere that contains hydrogen and that has been created as the reducing atmosphere.
